(19) United States
(12) Patent Application Publication
(10) Pub. No.: US 2024/0431140 A1
(43) Pub. Date: Dec. 26, 2024

(54) DISPLAY DEVICE

(71) Applicant: Samsung Display Co., LTD., Yongin-si (KR)

(72) Inventors: Chul SHIN, Yongin-si (KR); Jin Mo KWON, Yongin-si (KR); Won Jin SEO, Yongin-si (KR); Hwa An SUNG, Yongin-si (KR); Ji Young EOM, Yongin-si (KR); Dae Ho HWANG, Yongin-si (KR)

(73) Assignee: Samsung Display Co., LTD., Yongin-si (KR)

(21) Appl. No.: 18/420,144

(22) Filed: Jan. 23, 2024

(30) Foreign Application Priority Data
Jun. 26, 2023 (KR) 10-2023-0081750

(51) Int. Cl. H10K 59/121; H10K 59/35; H10K 102/10

(52) U.S. Cl. CPC H10K 59/121; H10K 59/353; H10K 2102/103

(57) ABSTRACT

A display device according to an embodiment includes a display area including a first display area and a second display area disposed around the first display area, a first pixel disposed in the first display area and including a first emission area, and a second pixel disposed in the second display area and including a second emission area, wherein the second emission area has a larger size than the first emission area.

### CROSS REFERENCE TO RELATED APPLICATION(S)

This application claims to and benefits of Korean Patent Application No. 10-2023-0081750, filed on Jun. 26, 2023, in the Korean Intellectual Property Office, the entire contents of which are incorporated herein by reference.

### BACKGROUND

### 1. Technical Field

Embodiments relate to a display device.

### 2. Description of the Related Art

Display devices are becoming increasingly important with the development of multimedia. Accordingly, various display devices such as liquid crystal display devices and organic light emitting display devices are being developed.

Pixels of a display device may deteriorate as the cumulative amount of light emission increases. For example, a pixel of an organic light emitting display device including an organic light emitting diode may not properly or accurately express a target luminance because deterioration of the organic light emitting diode accelerates as the amount and density of current flowing through the organic light emitting diode increase. For example, pixels positioned in an area where a specific image, such as a logo image or a banner image, is continuously or repeatedly displayed may deteriorate faster than other pixels. Accordingly, the image quality of the display device may degrade, afterimages may occur, and the lifespan of the display device may be shortened.

### SUMMARY

Embodiments provide a display device capable of reducing or minimizing deterioration of pixels disposed in an area having a large cumulative amount of light emission.

However, embodiments of the disclosure are not limited to those set forth herein. The above and other embodiments of the disclosure will become more apparent to one of ordinary skill in the art to which the disclosure pertains by referencing the detailed description of the disclosure given below.

According to an aspect of the disclosure, there is provided a display device including a display area including a first display area and a second display area disposed around the first display area, a first pixel disposed in the first display area and including a first emission area, and a second pixel disposed in the second display area and including a second emission area, wherein the second emission area has a larger size than the first emission area.

In an embodiment, the first pixel and the second pixel may include a same number of subpixels, and a sum of sizes of sub-emission areas of the subpixels of the second pixel may be greater than the sum of sizes of sub-emission areas of the subpixels of the first pixel.

In an embodiment, each of the first pixel and the second pixel may include a first-color subpixel emitting light of a first color, the first-color subpixel of the first pixel includes a first-color first sub-emission area having a first size, and the first-color subpixel of the second pixel may include a first-color second sub-emission area having a second size larger than the first size.

In an embodiment, the first-color subpixel of the first pixel may include an organic light emitting diode which includes a light emitting layer having a size corresponding to a size of the first-color first sub-emission area, and the first-color subpixel of the second pixel may include an organic light emitting diode which includes a light emitting layer having a size corresponding to a size of the first-color second sub-emission area.

In an embodiment, each of the first pixel and the second pixel may include a second-color subpixel emitting light of a second color, and the second-color subpixel of the second pixel may include a second-color second sub-emission area having a larger size than a second-color first sub-emission area of the second-color subpixel of the first pixel.

In an embodiment, each of the first pixel and the second pixel may include a third-color subpixel emitting light of a third color, and the third-color subpixel of the second pixel may include a third-color second sub-emission area having a larger size than a third-color first sub-emission area of the third-color subpixel of the first pixel.

In an embodiment, the first pixel and the second pixel may include different numbers of subpixels, and the second pixel may include a larger number of subpixels than the first pixel.

In an embodiment, the first pixel may include a first-color subpixel emitting light of a first color, a second-color subpixel emitting light of a second color and a third-color subpixel emitting light of a third color, and the second pixel may include a first-color subpixel emitting light of the first color, a second-color subpixel emitting light of the second color, a third-color subpixel emitting light of the third color, and a fourth-color subpixel emitting light of a fourth color.

In an embodiment, the first-color subpixel of the first pixel and the first-color subpixel of the second pixel may include sub-emission areas having a same size, the second-color subpixel of the first pixel and the second-color subpixel of the second pixel may include sub-emission areas having a same size, and the third-color subpixel of the first pixel and the third-color subpixel of the second pixel may include sub-emission areas having a same size.

In an embodiment, the light of the first color, the light of the second color, the light of the third color, and the light of the fourth color may be red light, green light, blue light, and white light, respectively.

In an embodiment, the first display area may be disposed at a center portion of the display area in at least a first direction, and the second display area may be disposed at edge portions of the display area in the first direction.

In an embodiment, the second display area may be disposed at the edge portions of the display area in the first direction and a second direction intersecting the first direction and may surround the first display area.

In an embodiment, the first direction may correspond to a vertical direction of the display area, and the second display area may be disposed at least one of an upper edge portion and a lower edge portion of the display area.

In an embodiment, the display area may display an image including a logo image or a banner image, and the second display area may include an area where the logo image or the banner image is displayed.

In an embodiment, the display area may further include a third display area disposed between the first display area and the second display area, and the third display area may include a third pixel.

In an embodiment, the third pixel may include a third emission area having a larger size than the first emission area and a smaller size than the second emission area.

According to an aspect of the disclosure, there is provided a display device including a first display area including a first pixel, and a second display area disposed on sides of the first display area in at least a first direction and including a second pixel, wherein the first pixel includes a first-color subpixel emitting light of a first color and including a sub-emission area having a first size, and the second pixel includes a first-color subpixel emitting light of the first color and including a sub-emission area having a second size larger than the first size.

In an embodiment, the first pixel and the second pixel may include a same number of subpixels.

According to an aspect of the disclosure, there is provided a display device including a first display area including a first pixel, and a second display area disposed on sides of the first display area in at least a first direction and including a second pixel, wherein each of the first pixel and the second pixel includes at least two subpixels, and the second pixel includes a larger number of subpixels than the first pixel.

In an embodiment, each of the first pixel and the second pixel may include a first-color subpixel emitting light of a first color, and the first-color subpixel of the first pixel and the first-color subpixel of the second pixel may include sub-emission areas having a same size.

A display device according to embodiments includes a first display area and a second display area disposed outside the first display area. A second pixel disposed in the second display area may include an emission area having a larger size than an emission area of a first pixel disposed in the first display area. For example, in embodiments, in the second display area in which a specific image displayed continuously and/or repeatedly, such as a logo image or a banner image, is frequently displayed, the area of the emission area of the second pixel disposed in the second display area may be expanded. Accordingly, the density of a current flowing through an organic light emitting diode disposed in the second pixel may be reduced, thereby reducing or minimizing deterioration of the second pixel.

According to embodiments, it is possible to reduce or minimize deterioration of organic light emitting diodes and pixels including the organic light emitting diodes disposed in the second display area by reducing the density of a current flowing through the organic light emitting diodes of the pixels disposed in the second display area which has a larger cumulative amount of light emission than the first display area. Accordingly, the image quality of the display device may be improved, and the lifespan of the display device may be extended.

However, effects according to the embodiments are not limited to those exemplified above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a display device according to an embodiment;

FIG. 2 is a schematic plan view of the display device according to the embodiment;

FIG. 3 is a schematic plan view of a pixel according to an embodiment;

FIG. 4 is a schematic plan view of a pixel according to an embodiment;

FIG. 5 is a schematic plan view of a pixel according to an embodiment;

FIG. 6 is a schematic plan view of a pixel according to an embodiment;

FIG. 7 is a schematic plan view of a pixel according to an embodiment;

FIG. 8 is a schematic diagram of an equivalent circuit of a subpixel according to an embodiment;

FIG. 9 is a schematic plan view of a display device according to an embodiment;

FIG. 10 is a schematic plan view of a display device according to an embodiment;

FIG. 11 is a schematic plan view illustrating a first pixel and a second pixel according to an embodiment;

FIG. 12 is a schematic cross-sectional view of a display device according to an embodiment;

FIG. 13 is a schematic plan view illustrating a first pixel and a second pixel according to an embodiment;

FIG. 14 is a schematic plan view of a display device according to an embodiment;

FIG. 15 is a schematic plan view of a display device according to an embodiment;

FIG. 16 is a schematic plan view illustrating a first pixel, a second pixel, and a third pixel according to an embodiment;

FIG. 17 is a schematic cross-sectional view of a display device according to an embodiment;

FIG. 18 is a schematic plan view illustrating a first pixel, a second pixel, and a third pixel according to an embodiment; and

FIG. 19 is a graph illustrating the luminance maintenance rate of a light emitting element with respect to light emission time and light emission luminance.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Features of each of various embodiments of the disclosure may be partially or entirely combined with each other and may technically variously interwork with each other, and respective embodiments may be implemented independently of each other or may be implemented together in association with each other.

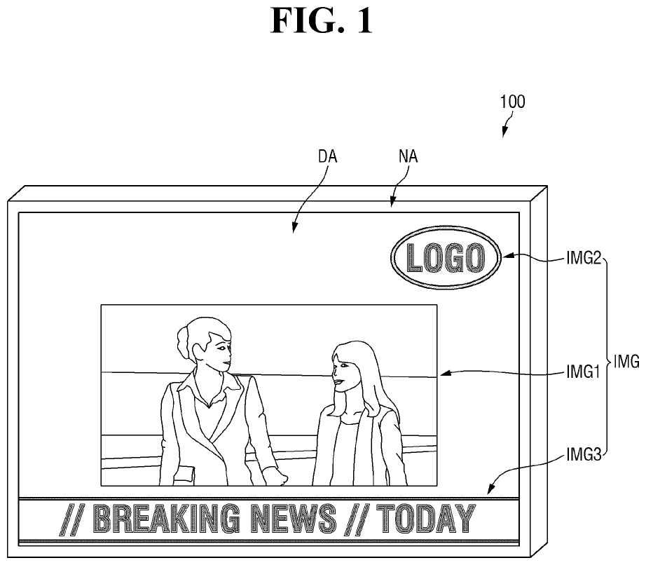

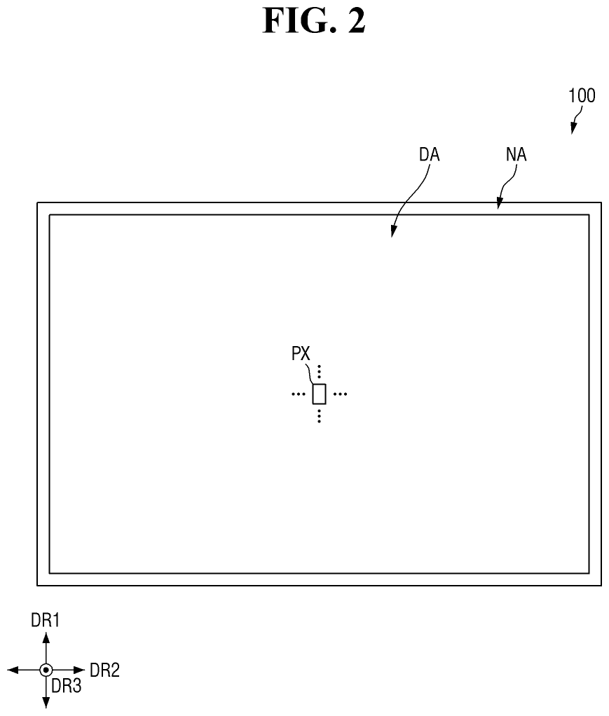

FIG. 1 is a schematic perspective view of a display device 100 according to an embodiment. FIG. 2 is a schematic plan view of the display device 100 of FIG. 1.

Referring to FIGS. 1 and 2, the display device 100 may include a display area DA and a non-display area NA (also referred to as a “bezel area”) positioned around the display area DA. Pixels PX may be provided or arranged in the display area DA. The non-display area NA may be an area other than the display area DA. For example, wirings, pads and/or an embedded circuit unit connected to the pixels PX may be provided or disposed in the non-display area NA.

The display device 100 may have various shapes. For example, the display device 100 may be formed in the form of a panel having a rectangular shape in a plane defined by a first direction DR1 and a second direction DR2 intersecting each other (or in plan view). However, embodiments are not limited thereto. For example, the display device 100 may also be provided in a polygonal shape other than a quadrilateral shape, a circular shape, or an elliptical shape. For example, the display device 100 may include angled corners and/or curved corners and may be formed in a substantially flat shape or a shape including a curved surface. For convenience of description, in FIGS. 1 and 2, the display device 100 is illustrated as having a rectangular shape and being flat when viewed in a plane defined by the first direction DR1 and the second direction DR2 (or in plan view).

In FIG. 2, a direction (e.g., a vertical direction) in which short sides of the display device 100 extend is illustrated as the first direction DR1, and a direction (e.g., a horizontal direction) in which long sides extend is illustrated as the second direction DR2. The display device 100 may have a thickness or height in a third direction DR3 intersecting the first direction DR1 and the second direction DR2. For example, the third direction DR3 may be a direction orthogonal to the first direction DR1 and the second direction DR2 and may be a thickness direction (or height direction) of the display device 100.

The display area DA may have various shapes. For example, the display area DA may have various shapes including a quadrangular shape, a polygonal shape other than the quadrangular shape, a circular shape, and an elliptical shape. In an embodiment, the display area DA may have a shape conforming (or corresponding) to the shape of the display device 100, but embodiments are not limited thereto.

The screen of the display device 100 including the display area DA may be substantially flat or may have a curved surface. The shape of the display area DA and the shape of the display device 100 including the display area DA may be variously changed (or modified) according to embodiments.

The display area DA may include pixels PX, and an image IMG may be displayed in the display area DA by the pixels PX. In an embodiment, the image IMG may include a display image IMG1 (also referred to as a “first image”) including the general content of a program and may further include a logo image IMG2 and/or a banner image IMG3 that are continuously and repeatedly displayed when a certain broadcast and/or program is aired. The logo image IMG2 or the banner image IMG3 may be continuously and/or repeatedly displayed at a specific position in the display area DA, for example, in an edge area including upper and lower edge portions of the display area DA. Accordingly, pixels PX positioned in an area where a specific image displayed continuously and/or repeatedly, such as the logo image IMG2 or the banner image IMG3, is frequently displayed may have a relatively larger cumulative amount of light emission than other pixels PX and may deteriorate or degrade faster than other pixels PX.

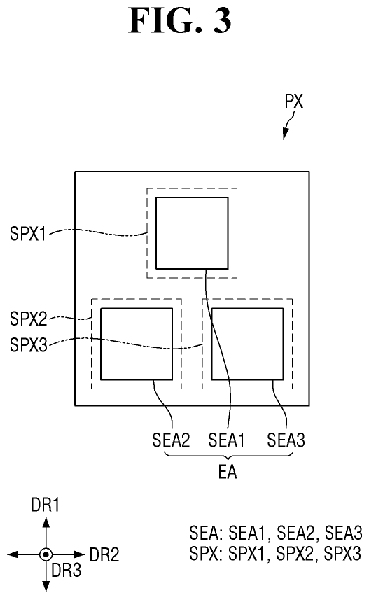

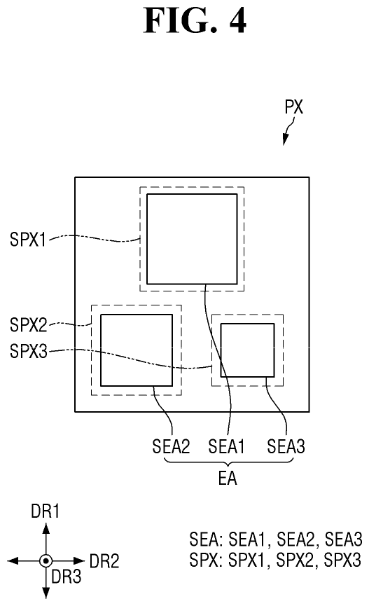

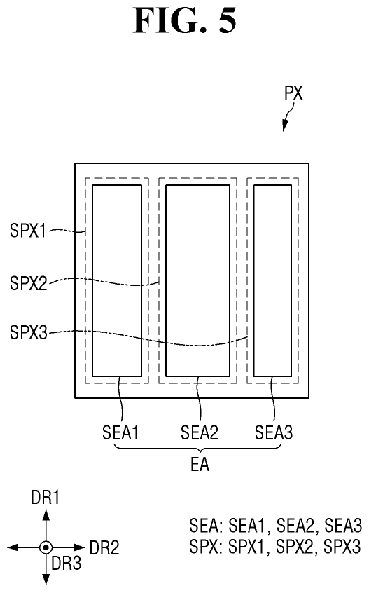

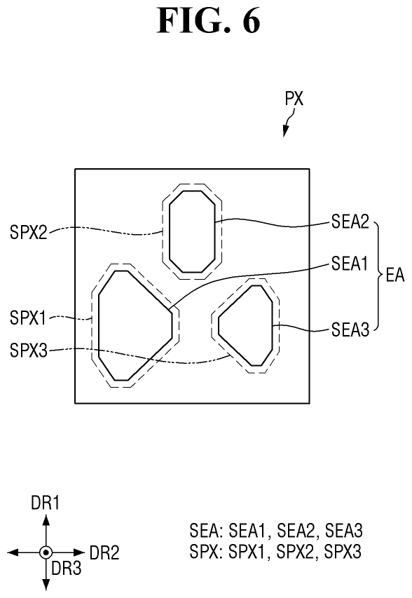

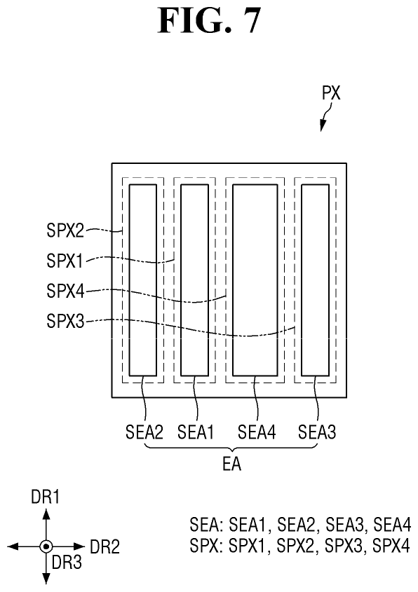

FIG. 3 is a schematic plan view of a pixel PX according to an embodiment. FIG. 4 is a schematic plan view of a pixel PX according to an embodiment. FIG. 5 is a schematic plan view of a pixel PX according to an embodiment. FIG. 6 is a schematic plan view of a pixel PX according to an embodiment. FIG. 7 is a schematic plan view of a pixel PX according to an embodiment. For example, FIGS. 3, 4, 5, 6, and 7 show different embodiments in relation to the configuration, shape, and/or arrangement structure of a pixel PX that is provided or arranged in the display area DA of FIGS. 1 and 2.

Referring to FIGS. 3, 4, 5, 6, and 7, a pixel PX may include at least two subpixels SPX respectively including sub-emission areas SEA. The pixel PX may include an emission area EA including the sub-emission areas SEA of the subpixels SPX. For example, the emission area EA of each pixel PX may include the sub-emission areas SEA of the subpixels SPX disposed in the pixel PX.

Each subpixel SPX may include at least one light emitting element (e.g., organic light emitting diode) disposed in the sub-emission area SEA. In an embodiment, each subpixel SPX may further include a pixel circuit connected to the light emitting element. In embodiments, the term “connection” may mean physical connection and/or electrical connection.

In some embodiments, the pixel PX may include a first-color subpixel SPX1 (also referred to as a “first subpixel”) emitting light of a first color (e.g., red light), a second-color subpixel SPX2 (also referred to as a “second subpixel”) emitting light of a second color (e.g., green light), and a third-color subpixel SPX3 (also referred to as a “third subpixel”) emitting light of a third color (e.g., blue light).

The first-color subpixel SPX1 may include a first-color sub-emission area SEA1 (e.g., an emission area of the first-color subpixel SPX1) having a light emitting element (e.g., an organic light emitting diode) and emitting light of the first color. In an embodiment, the first-color subpixel SPX1 may include a light emitting element (e.g., a red organic light emitting diode) emitting light of the first color or may include a light emitting element emitting light of a specific color and a wavelength converter converting the light of the specific color into the light of the first color. Accordingly, the light of the first color may be emitted from the first-color sub-emission area SEA1.

The second-color subpixel SPX2 may include a second-color sub-emission area SEA2 (e.g., an emission area of the second-color subpixel SPX2) having a light emitting element (e.g., an organic light emitting diode) and emitting light of the second color. In an embodiment, the second-color subpixel SPX2 may include a light emitting element (e.g., a green organic light emitting diode) emitting light of the second color or may include a light emitting element emitting light of a specific color and a wavelength converter converting the light of the specific color into the light of the second color. Accordingly, the light of the second color may be emitted from the second-color sub-emission area SEA2.

The third-color subpixel SPX3 may include a third-color sub-emission area SEA3 (e.g., an emission area of the third-color subpixel SPX3) having a light emitting element (e.g., an organic light emitting diode) and emitting light of the third color. In an embodiment, the third-color subpixel SPX3 may include a light emitting element (e.g., a blue organic light emitting diode) emitting light of the third color or may include a light emitting element emitting light of a specific color and a wavelength converter converting the light of the specific color into the light of the third color. Accordingly, the light of the third color may be emitted from the third-color sub-emission area SEA3.

Although the embodiments in which one first-color subpixel SPX1, one second-color subpixel SPX2, one third-color subpixel SPX3, and/or one fourth-color subpixel SPX4 are included in each pixel PX are disclosed in FIGS. 3, 4, 5, 6, and 7, embodiments are not limited thereto. For example, two or more subpixels SPX emitting light of the same color may also be disposed in each pixel PX. The type and/or number of subpixels SPX included in each pixel PX may be variously changed (or modified) according to embodiments.

Each subpixel SPX may include a sub-emission area SEA having a quadrangular shape, a polygonal shape other than the quadrangular shape, a circular shape, an elliptical shape, or other shapes. For example, the shape, size, ratio and/or arrangement structure of the sub-emission areas SEA formed in each pixel PX may be variously changed (or modified) so that target values for various characteristics such as aperture ratio, transmittance, luminous efficiency, white balance and/or visibility of each subpixel SPX and the pixel PX including the subpixels SPX may be achieved.

In some embodiments, as illustrated in FIGS. 3 and 4, the pixel PX may include sub-emission areas SEA having a quadrangular shape such as a square shape and arranged in a delta shape. In an embodiment, the sub-emission areas SEA of each pixel PX may have substantially the same or similar sizes as illustrated in FIG. 3. In an embodiment, at least two sub-emission areas SEA of each pixel PX may have different sizes. For example, as illustrated in FIG. 4, the sub-emission areas SEA of each pixel PX may have different sizes.

In an embodiment, the pixel PX may include sub-emission areas SEA arranged in a stripe shape along a direction. For example, as illustrated in FIG. 5, the pixel PX may include sub-emission areas SEA having a rectangular shape extending in the first direction DR1 and sequentially arranged along the second direction DR2. In an embodiment, the first-color sub-emission area SEA1, the second-color sub-emission area SEA2, and the third-color sub-emission area SEA3 may be sequentially arranged along the second direction DR2. However, the arrangement order of the sub-emission areas SEA may be changed or modified. The sub-emission areas SEA may have the same area (or size) or different areas (or sizes).

In an embodiment, the pixel PX may include sub-emission areas SEA having a non-quadrangular shape. For example, as illustrated in FIG. 6, the pixel PX may include sub-emission areas SEA having a polygonal shape other than a quadrangular shape and arranged in a delta shape. The sub-emission areas SEA may have the same area (or size) or different areas (or sizes). The arrangement order of the sub-emission areas SEA may be variously changed (or modified) according to embodiments.

In an embodiment, as illustrated in FIG. 7, the pixel PX may further include a fourth-color subpixel SPX4 (also referred to as a “fourth subpixel”) emitting light of a fourth color (e.g., white light). The fourth-color subpixel SPX4 may include a fourth-color sub-emission area SEA4 (e.g., an emission area of the fourth-color subpixel SPX4) having a light emitting element (e.g., an organic light emitting diode) and emitting light of the fourth color. In an embodiment, the fourth-color subpixel SPX4 may include a light emitting element (e.g., a white organic light emitting diode) emitting light of the fourth color or may include a light emitting element emitting light of a specific color and a wavelength converter converting the light of the specific color into the light of the fourth color. Accordingly, the light of the fourth color may be emitted from the fourth-color sub-emission area SEA4. In an embodiment, the pixel PX may include sub-emission areas SEA having a rectangular shape extending in the first direction DR1 and sequentially arranged along the second direction DR2. In an embodiment, the second-color sub-emission area SEA2, the first-color sub-emission area SEA1, the fourth-color sub-emission area SEA4, and the third-color sub-emission area SEA3 may be sequentially arranged along the second direction DR2. However, the arrangement order of the sub-emission areas SEA may be changed or modified. The sub-emission areas SEA may have the same area (or size) or different areas (or sizes).

The display device 100 may also include pixels PX having various configurations, structures, and/or shapes other than the embodiments of FIGS. 3, 4, 5, 6, and 7.

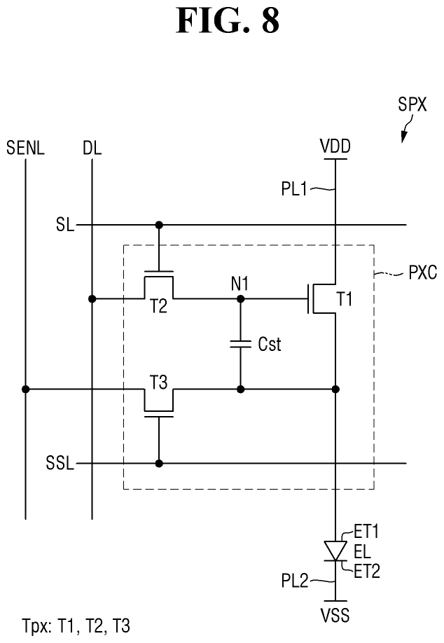

FIG. 8 is a schematic diagram of an equivalent circuit of a subpixel SPX according to an embodiment.

Referring to FIG. 8, the subpixel SPX may include a light emitting element EL formed between a first power line PL1 to which a first power supply voltage VDD is supplied and a second power line PL2 to which a second power supply voltage VSS is supplied. The light emitting element EL may be an organic light emitting diode. In an embodiment, the subpixel SPX may further include a pixel circuit PXC. However, embodiments are not limited thereto.

The pixel circuit PXC may be connected between the first power line PL1 and the light emitting element EL. For example, the pixel circuit PXC may be connected to a scan line SL (or a first scan line) and a data line DL of the subpixel SPX to control light emission of the light emitting element EL in response to a scan signal and a data signal supplied through the scan line SL and the data line DL. In an embodiment, the pixel circuit PXC may be further connected to a sensing control line SSL (or a second scan line) and a sensing line SENL (or an initialization power line).

The pixel circuit PXC may include at least one transistor Tpx and a capacitor Cst. For example, the pixel circuit PXC may include a first transistor T1, a second transistor T2, a third transistor T3, and the capacitor Cst. The configuration of the pixel circuit PXC may be variously changed (or modified) according to embodiments.

The first transistor T1 may be connected between the first power line PL1 and a first electrode ET1 (e.g., an anode) of the light emitting element EL. A gate electrode of the first transistor T1 may be connected to a first node N1. The first transistor T1 may control a driving current supplied to the light emitting element EL in response to a voltage of the first node N1. For example, the first transistor T1 may be a driving transistor that controls the driving current of the subpixel SPX.

The second transistor T2 may be connected between the data line DL and the first node N1. A gate electrode of the second transistor T2 may be connected to the scan line SL. The second transistor T2 may be turned on in case that a scan signal of a gate-on voltage (e.g., a high-level voltage) is supplied from the scan line SL and may electrically connect the data line DL and the first node N1.

A data signal supplied to the data line DL in each frame period may be transmitted to the first node N1 of the subpixel SPX including the second transistor T2 turned on in response to the scan signal of the gate-on voltage. For example, the second transistor T2 may be a switching transistor for transferring each data signal into the subpixel SPX.

An electrode of the capacitor Cst may be connected to the first node N1, and another electrode may be connected to a second electrode of the first transistor T1. The capacitor Cst may be charged with a voltage corresponding to a data signal supplied to the first node N1.

The third transistor T3 may be connected between the first electrode ET1 of the light emitting element EL (or the second electrode of the first transistor T1) and the sensing line SENL. A gate electrode of the third transistor T3 may be connected to the sensing control line SSL. The third transistor T3 may transmit, to the sensing line SENL, the value of a voltage supplied to the first electrode ET1 of the light emitting element EL according to a sensing signal of a gate-on voltage supplied to the sensing control line SSL during a sensing period. The voltage value received through the sensing line SENL may be provided to an external circuit (e.g., a timing controller), and the external circuit may extract characteristic information (e.g., a threshold voltage of the first transistor T1) of each subpixel SPX based on the received voltage value. The extracted characteristic information may be used to convert image data so that deviations in characteristics of subpixels SPX and pixels PX including the subpixels SPX may be compensated for.

In FIG. 8, the transistors Tpx, for example, the first, second, and third transistors T1, T2, and T3 included in the pixel circuit PXC may be all N-type transistors. However, embodiments are not limited thereto. For example, at least one of the first, second, and third transistors T1, T2, and T3 may also be changed (or modified) to a P-type transistor.

In addition to the embodiment illustrated in FIG. 8, the pixel circuit PXC may also be formed in various types, structures, and/or driving methods. For example, the pixel circuit PXC may not include the third transistor T3. For example, the pixel circuit PXC may further include other circuit elements such as a compensation transistor for compensating for the threshold voltage of the first transistor T1, an initialization transistor for initializing the voltage of the first node N1 and/or the first electrode ET1 of the light emitting element EL, an emission control transistor for controlling a period during which a driving current is supplied to the light emitting element EL, and/or a boosting capacitor for boosting the voltage of the first node N1. In an embodiment, in case that the subpixel SPX is a passive subpixel, the pixel circuit PXC may be omitted.

The light emitting element EL may include the first electrode ET1 connected to the first power line PL1 via the pixel circuit PXC and a second electrode ET2 connected to the second power line PL2. The light emitting element EL may further include a light emitting layer (e.g., an organic light emitting layer) interposed between the first electrode ET1 and the second electrode ET2.

The first power supply voltage VDD and the second power supply voltage VSS supplied to the first power line PL1 and the second power line PL2, respectively, may have different potentials so that the light emitting element EL may emit light. For example, the first power supply voltage VDD may be a high-potential pixel power supply voltage, and the second power supply voltage VSS may be a low-potential pixel power supply voltage. For example, the first electrode ET1 of the light emitting element EL may be an anode, and the second electrode ET2 of the light emitting element EL may be a cathode.

In case that a driving current is supplied from the pixel circuit PXC, the light emitting element EL may generate light having a luminance corresponding to the driving current. Accordingly, each subpixel SPX may emit light with a luminance corresponding to a data signal supplied to the first node N1 during each frame period.

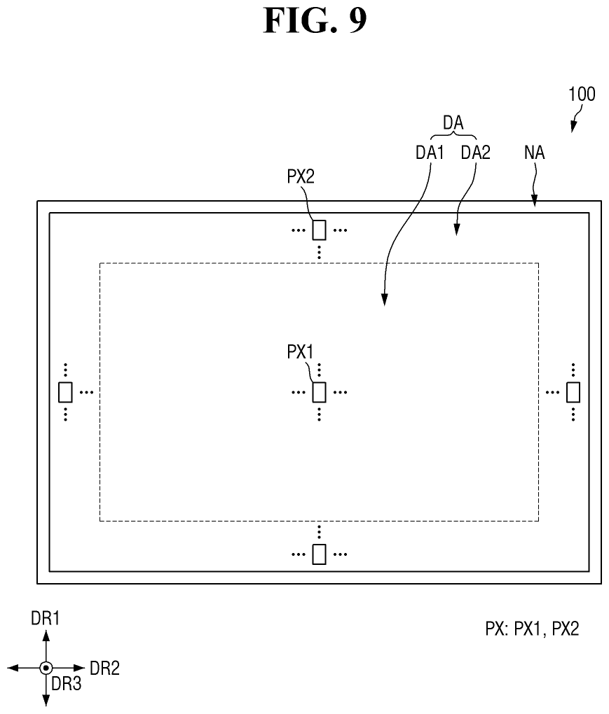

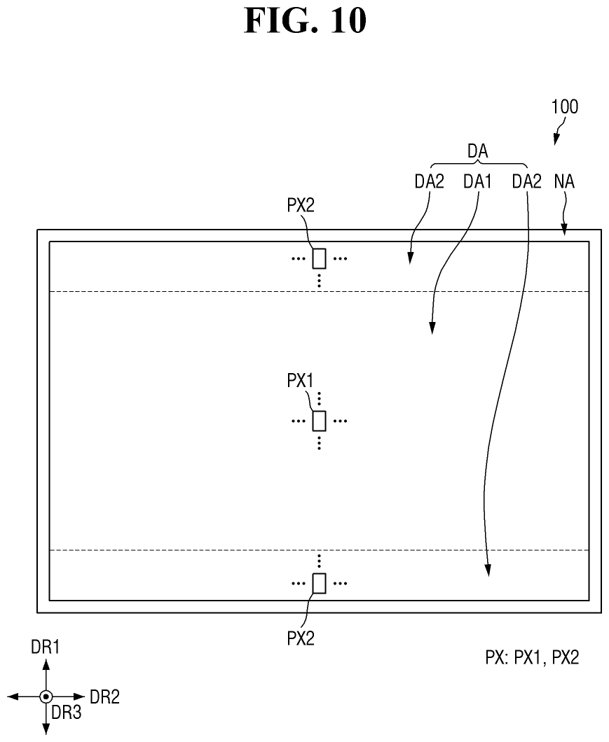

FIG. 9 is a schematic plan view of a display device 100 according to an embodiment. FIG. 10 is a schematic plan view of a display device 100 according to an embodiment. For example, FIGS. 9 and 10 show different embodiments in relation to a display area DA.

Referring to FIGS. 9 and 10 in addition to FIGS. 1 through 8, the display area DA may include a first display area DA1 including first pixels PX1 and at least one second display area DA2 including second pixels PX2. The first display area DA1 may be positioned at the center portion of the display area DA in at least the first direction DR1. The second display area DA2 may be positioned at edge portions of the display area DA in at least the first direction DR1. For example, the second display area DA2 may be positioned outside the first display area DA1. In an embodiment, the display area DA may display an image IMG including a logo image IMG2 and/or a banner image IMG3 corresponding to image data, and the second display area DA2 may include an area where the logo image IMG2 and/or the banner image IMG3 are displayed (e.g., an upper edge portion and/or a lower edge portion of the display area DA).

In an embodiment, as illustrated in FIG. 9, the first display area DA1 may be positioned at the center portion of the display area DA in the first direction DR1 and the second direction DR2. The second display area DA2 may be positioned at the edge portions of the display area DA in the first direction DR1 and the second direction DR2. For example, the second display area DA2 may be positioned on sides (e.g., opposite sides) of the first display area DA1 in the first direction DR1 and the second direction DR2 and may surround the first display area DA1.

In an embodiment, as illustrated in FIG. 10, the first display area DA1 may be positioned at the center portion of the display area DA in the first direction DR1, and the second display area DA2 may be positioned on at least one side of the first display area DA1 in the first direction DR1. For example, the second display area DA2 may be positioned on sides (e.g., opposite sides) of the first display area DA1 in the first direction DR1.

For example, the first direction DR1 may correspond to a vertical direction of the display area DA, and the display area DA may include the second display area DA2 positioned at at least one of the upper edge portion and the lower edge portion of the display area DA. For example, the display area DA may include two second display areas DA2 separated from each other with the first display area DA1 between the two second display areas DA2 and positioned at the upper and lower edge portions of the display area DA, respectively.

The display device 100 may include the first pixels PX1 positioned in the first display area DA1 and the second pixels PX2 positioned in the second display area DA2. The first pixels PX1 and the second pixels PX2 may include emission areas EA having different areas (or different sizes). For example, each of the second pixels PX2 positioned in the second display area DA2 may include an emission area EA having a relatively larger area (or larger size) than that of each of the first pixels PX1 positioned in the first display area DA1.

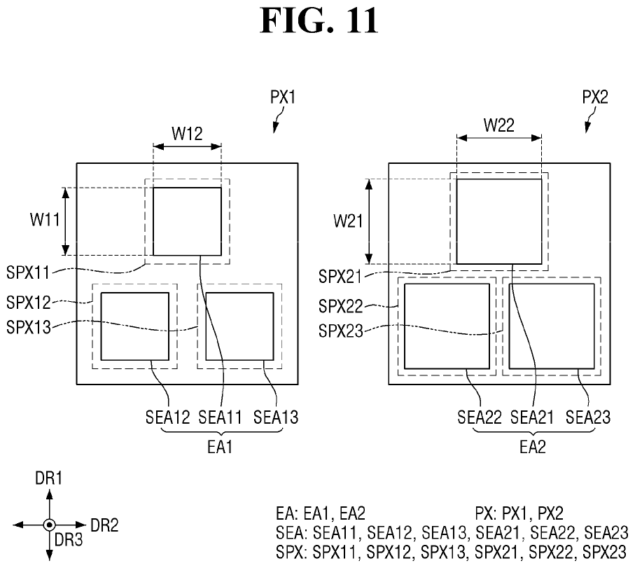

FIG. 11 is a schematic plan view illustrating a first pixel PX1 and a second pixel PX2 according to an embodiment. In FIG. 11, the first pixel PX1 and the second pixel PX2 are illustrated as being disposed side by side for comparison between the first pixel PX1 and the second pixel PX2.

Referring to FIG. 11 in addition to FIGS. 1 through 10, pixels PX including the first pixel PX1 and the second pixel PX2 may each include at least two subpixels SPX including sub-emission areas SEA, respectively. For example, each of the pixels PX including the first pixel PX1 and the second pixel PX2 may include an emission area EA including sub-emission areas SEA of the pixel PX. For example, the first pixel PX1 may include a first emission area EA1 including sub-emission areas SEA of the first pixel PX1 (e.g., an emission area EA of the first pixel PX1), and the second pixel PX2 may include a second emission area EA2 including sub-emission areas SEA of the second pixel PX2 (e.g., an emission area EA of the second pixel PX2).

In an embodiment, the first pixel PX1 may include a first-color subpixel SPX11 emitting light of a first color, a second-color subpixel SPX12 emitting light of a second color, and a third-color subpixel SPX13 emitting light of a third color. The first-color subpixel SPX11 of the first pixel PX1 may include a first-color first sub-emission area SEA11 having a light emitting element and emitting light of the first color (e.g., an emission area of the first-color subpixel SPX11 included in the first pixel PX1). The second-color subpixel SPX12 of the first pixel PX1 may include a second-color first sub-emission area SEA12 having a light emitting element and emitting light of the second color (e.g., an emission area of the second-color subpixel SPX12 included in the first pixel PX1). The third-color subpixel SPX13 of the first pixel PX1 may include a third-color first sub-emission area SEA13 having a light emitting element and emitting light of the third color (e.g., an emission area of the third-color subpixel SPX13 included in the first pixel PX1). The first emission area EA1 of the first pixel PX1 may include the first-color first sub-emission area SEA11, the second-color first sub-emission area SEA12, and the third-color first sub-emission area SEA13.

In an embodiment, the second pixel PX2 may include the same type, the same configuration, and/or the same number of subpixels SPX as the first pixel PX1. For example, the first pixel PX1 and the second pixel PX2 may include the same type and the same number of subpixels SPX.

In an embodiment, the second pixel PX2 may include a first-color subpixel SPX21 emitting light of the first color, a second-color subpixel SPX22 emitting light of the second color, and a third-color subpixel SPX23 emitting light of the third color. The first-color subpixel SPX21 of the second pixel PX2 may include a first-color second sub-emission area SEA21 having a light emitting element and emitting light of the first color (e.g., an emission area of the first-color subpixel SPX21 included in the second pixel PX2). The second-color subpixel SPX22 of the second pixel PX2 may include a second-color second sub-emission area SEA22 having a light emitting element and emitting light of the second color (e.g., an emission area of the second-color subpixel SPX22 included in the second pixel PX2). The third-color subpixel SPX23 of the second pixel PX2 may include a third-color second sub-emission area SEA23 having a light emitting element and emitting light of the third color (e.g., an emission area of the third-color subpixel SPX23 included in the second pixel PX2). The second emission area EA2 of the second pixel PX2 may include the first-color second sub-emission area SEA21, the second-color second sub-emission area SEA22, and the third-color second sub-emission area SEA23.

The second emission area EA2 may have a larger area (or larger size) than the first emission area EA1. For example, the sum of the areas (or sizes) of the sub-emission areas SEA included in the subpixels SPX of the second pixel PX2 may be greater than the sum of the areas (or sizes) of the sub-emission areas SEA included in the subpixels SPX of the first pixel PX1. For example, the sum of the areas (or sizes) of the first-color second sub-emission area SEA21, the second-color second sub-emission area SEA22, and the third-color second sub-emission area SEA23 included in the first, second and third subpixels SPX21, SPX22 and SPX23 of the second pixel PX2 may be greater than the sum of the areas (or sizes) of the first-color first sub-emission area SEA11, the second-color first sub-emission area SEA12, and the third-color first sub-emission area SEA13 included in the first, second and third subpixels SPX11, SPX12 and SPX13 of the first pixel PX1, respectively.

In an embodiment, at least some of the sub-emission areas SEA included in the first pixel PX1 and the second pixel PX2 and corresponding to each other may have different areas (or different sizes). For example, at least one sub-emission area SEA included in the second pixel PX2 may have a greater width than a corresponding sub-emission area SEA of the first pixel PX1 in at least one of the first direction DR1 and the second direction DR2. For example, the first-color first sub-emission area SEA11 of the first pixel PX1 may have a first width W11 in the first direction DR1 and a second width W12 in the second direction DR2, and the first-color second sub-emission area SEA21 of the second pixel PX2 may have a third width W21 in the first direction DR1 and a fourth width W22 in the second direction DR2. For example, the third width W21 may be greater than the first width W11, and/or the fourth width W22 may be greater than the second width W12. Accordingly, the area (also referred to as “second area” or “second size”) of the first-color second sub-emission area SEA21 may be larger than the area (also referred to as “first area” or “first size”) of the first-color first sub-emission area SEA11.

In an embodiment, the second-color second sub-emission area SEA22 may have a greater width than the second-color first sub-emission area SEA12 in at least one of the first direction DR1 and the second direction DR2. Accordingly, the area (or size) of the second-color second sub-emission area SEA22 may be larger than the area (or size) of the second-color first sub-emission area SEA12.

In an embodiment, the third-color second sub-emission area SEA23 may have a greater width than the third-color first sub-emission area SEA13 in at least one of the first direction DR1 and the second direction DR2. Accordingly, the area (or size) of the third-color second sub-emission area SEA23 may be larger than the area (or size) of the third-color first sub-emission area SEA13. For example, each sub-emission area SEA included in the second pixel PX2 may have a larger area (or larger size) than a sub-emission area SEA of the first pixel PX1 which corresponds to the sub-emission area SEA.

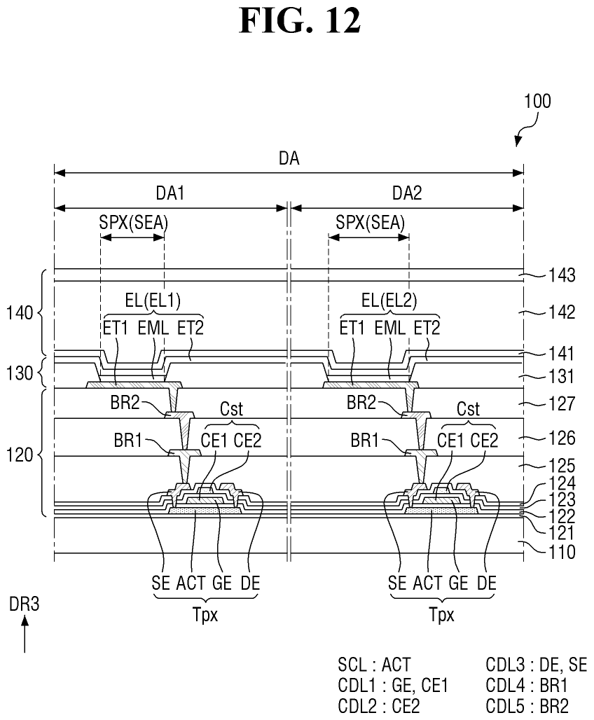

FIG. 12 is a schematic cross-sectional view of a display device 100 according to an embodiment. For example, FIG. 12 schematically illustrates a cross-section of a portion of a display area DA corresponding to an area where two subpixels SPX respectively positioned in a first display area DA1 and a second display area DA2 are disposed. FIG. 12 schematically illustrates cross-sections of one transistor Tpx (e.g., the first transistor T1 of FIG. 8), a capacitor Cst, and a light emitting element EL among elements disposed in each subpixel SPX. The cross-sections of the subpixels SPX may be variously changed (or modified) according to the type and/or structure of each subpixel SPX and the display device 100 including the subpixels SPX.

Referring to FIG. 12 in addition to FIGS. 1 through 11, the display device 100 may include a substrate 110 and a circuit layer 120, a light emitting element layer 130 and an encapsulation layer 140 disposed on the substrate 110. In an embodiment, the circuit layer 120, the light emitting element layer 130, and the encapsulation layer 140 may be sequentially disposed or stacked on the substrate 110 along the third direction DR3.

The substrate 110 may be made of a flexible material that is bendable, foldable, or rollable. The substrate 110 may be made of an insulating material such as polymer resin. For example, the substrate 110 may be made of polyimide (PI).

The circuit layer 120 may include pixel circuits PXC of the subpixels SPX (e.g., circuit elements of the pixel circuit PXC of each subpixel SPX) and wirings (e.g., scan lines SL, data lines DL, sensing control lines SSL, sensing lines SENL, a first power line PL1 and/or a second power line PL2) connected to the subpixels SPX. For example, the circuit layer 120 may include the transistor Tpx and the capacitor Cst disposed in each subpixel SPX. The transistor Tpx may be electrically connected to the light emitting element EL of a corresponding subpixel SPX. Each transistor Tpx may include an active layer ACT, a gate electrode GE, a source electrode SE, and a drain electrode DE.

The circuit layer 120 may include conductive layers for forming circuit elements and wirings, at least one semiconductor layer SCL, and insulating layers disposed between the conductive layers and the semiconductor layer SCL. For example, the circuit layer 120 may include a buffer layer 121, the semiconductor layer SCL (or a first semiconductor layer), a first insulating layer 122 (e.g., a first gate insulating layer), a first conductive layer CDL1 (e.g., a first gate conductive layer), a second insulating layer 123 (e.g., a second gate insulating layer), a second conductive layer CDL2 (e.g., a second gate conductive layer), a third insulating layer 124 (e.g., an interlayer insulating layer or a first interlayer insulating layer), a third conductive layer CDL3 (e.g., a first source-drain conductive layer), a fourth insulating layer 125 (e.g., a first via layer or a first planarization layer), a fourth conductive layer CDL4 (e.g., a second source-drain conductive layer), a fifth insulating layer 126 (e.g., a second via layer or a second planarization layer), a fifth conductive layer CDL5 (e.g., a third source-drain conductive layer), and a sixth insulating layer 127 (e.g., a third via layer or a third planarization layer) sequentially disposed on the substrate 110 in the third direction DR3.

The buffer layer 121 may include at least one inorganic layer including an inorganic insulating material (e.g., silicon nitride, silicon oxide, silicon oxynitride, titanium oxide, aluminum oxide, or other inorganic insulating materials). However, embodiments are not limited thereto, and the material of the buffer layer 121 may be changed or modified.

In an embodiment, an additional conductive layer may be disposed between the substrate 110 and the buffer layer 121. For example, a conductive layer including a light blocking layer or a back-gate electrode, which overlaps the active layer ACT of at least one transistor Tpx, and/or including at least one wiring (or a portion of the at least one wiring) may be disposed between the substrate 110 and the buffer layer 121.

The semiconductor layer SCL may be disposed on a surface of the substrate 110 including the buffer layer 121. The semiconductor layer SCL may include the active layer ACT of each transistor Tpx. Each active layer ACT may include polycrystalline silicon, monocrystalline silicon, low-temperature polycrystalline silicon, amorphous silicon, or an oxide semiconductor material. Each active layer ACT may include a channel region, a source region, and a drain region.

The first insulating layer 122 may cover the semiconductor layer SCL. In an embodiment, the first insulating layer 122 may include at least one inorganic layer including an inorganic insulating material.

The first conductive layer CDL1 may be disposed on the first insulating layer 122. The first conductive layer CDL1 may include the gate electrode GE of each transistor Tpx. Each gate electrode GE may include a conductive material (e.g., at least one of molybdenum (Mo), aluminum (Al), chromium (Cr), gold (Au), titanium (Ti), nickel (Ni), neodymium (Nd), copper (Cu) and other metals, an alloy thereof, or other conductive materials) and may be a single-layer electrode or a multilayer electrode.

The first conductive layer CDL1 may further include at least one wiring (or a portion of the at least one wiring), a bridge pattern layer, and/or a capacitor electrode. For example, the first conductive layer CDL1 may further include a first capacitor electrode CE1 of each capacitor Cst. In an embodiment, the first capacitor electrode CE1 may be integral with the gate electrode GE of a transistor (e.g., pixel transistor) Tpx connected to the first capacitor electrode CE1. For example, the first capacitor electrode CE1 may be integral with the gate electrode GE of a transistor (e.g., pixel transistor) Tpx whose gate electrode is connected to a capacitor Cst. See, e.g., the first transistor T1 of FIG. 8.

The second insulating layer 123 may cover the first conductive layer CDL1. In an embodiment, the second insulating layer 123 may include at least one inorganic layer including an inorganic insulating material.

The second conductive layer CDL2 may be disposed on the second insulating layer 123. The second conductive layer CDL2 may include at least one wiring (or a portion of the at least one wiring), a bridge pattern layer, and/or a capacitor electrode. For example, the second conductive layer CDL2 may include a second capacitor electrode CE2 of each capacitor Cst.

In an embodiment, in case that each pixel PX further includes at least one transistor, which is different from the transistors Tpx illustrated in FIG. 12, and/or in case that the at least one transistor and the transistors Tpx illustrated in FIG. 12 are formed on different layers, the second conductive layer CDL2 may further include a gate electrode or a bottom metal layer of the at least one transistor.

The third insulating layer 124 may cover the second conductive layer CDL2. In an embodiment, the third insulating layer 124 may include at least one inorganic layer including an inorganic insulating material.

The third conductive layer CDL3 may be formed on the third insulating layer 124. The third conductive layer CDL3 may include the source electrode SE and the drain electrode DE of each transistor Tpx. Each of the source electrode SE and the drain electrode DE may include a conductive material and may be a single-layer electrode or a multilayer electrode. In an embodiment, the source electrode SE and the drain electrode DE of each transistor Tpx may be formed as the source region and the drain region of the active layer ACT, and the third conductive layer CDL3 may include a bridge pattern layer connected to the source electrode SE or the drain electrode DE of at least one transistor Tpx. In an embodiment, the third conductive layer CDL3 may further include at least one wiring (or a portion of the at least one wiring), a bridge pattern layer, and/or a capacitor electrode. For example, the third conductive layer CDL3 may further include the first power line PL1 (or a portion of the first power line PL1) and/or the second power line PL2 (or a portion of the second power line PL2).

The fourth insulating layer 125 may cover the third conductive layer CDL3. In an embodiment, the fourth insulating layer 125 may include at least one organic layer including an organic insulating material (e.g., acryl resin, epoxy resin, phenolic resin, polyamide resin, polyimide resin, or other organic insulating materials) to planarize the circuit layer 120.

The fourth conductive layer CDL4 may be formed on the fourth insulating layer 125. The fourth conductive layer CDL4 may include first bridge electrodes BR1 (or first connection electrodes) connecting the transistors Tpx to the light emitting elements EL, respectively. The first bridge electrodes BR1 may be disposed on the transistors Tpx, respectively, and may electrically connect the transistors Tpx to the light emitting elements EL of a corresponding pixel PX. Each of the first bridge electrodes BR1 may include a conductive material and may be a single-layer electrode or a multilayer electrode. In an embodiment, the fourth conductive layer CDL4 may further include at least one wiring (or a portion of the at least one wiring), a bridge pattern, and/or a capacitor electrode. For example, the fourth conductive layer CDL4 may further include the first power line PL1 (or a portion of the first power line PL1) and/or the second power line PL2 (or a portion of the second power line PL2).

The fifth insulating layer 126 may cover the fourth conductive layer CDL4. In an embodiment, the fifth insulating layer 126 may include at least one organic layer including an organic insulating material (e.g., acryl resin, epoxy resin, phenolic resin, polyamide resin, polyimide resin, or other organic insulating materials) to planarize the circuit layer 120.

The fifth conductive layer CDL5 may be formed on the fifth insulating layer 126. The fifth conductive layer CDL5 may include second bridge electrodes BR2 (or second connection electrodes) connecting the transistors Tpx (or the first bridge electrodes BR1) to the light emitting elements EL, respectively. For example, the second bridge electrodes BR2 may be disposed on the first bridge electrodes BR1, respectively, and may electrically connect the first bridge electrodes BR1 to the light emitting elements EL of a corresponding pixel PX. Each of the second bridge electrodes BR2 may include a conductive material and may be a single-layer electrode or a multilayer electrode. In an embodiment, the fifth conductive layer CDL5 may further include at least one wiring (or a portion of the at least one wiring) and/or a bridge pattern layer. For example, the fifth conductive layer CDL5 may include a portion of the first power line PL1 and/or the second power line PL2.

The sixth insulating layer 127 may cover the fifth conductive layer CDL5. In an embodiment, the sixth insulating layer 127 may include at least one organic layer including an organic insulating material (e.g., an organic insulating material exemplified as the material of the fourth insulating layer 125 or other organic insulating materials) to planarize the circuit layer 120.

The light emitting element layer 130 may include a pixel defining layer 131 separating the sub-emission areas SEA and the light emitting elements EL positioned in the sub-emission areas SEA, respectively. For example, the light emitting element layer 130 may include a first light emitting element EL1 disposed in a sub-emission area SEA of a subpixel SPX (e.g., any one sub-emission area SEA of a first pixel PX1) positioned in the first display area DA1 and a second light emitting element EL2 disposed in a sub-emission area SEA of a subpixel SPX (e.g., any one sub-emission area SEA of a second pixel PX2) positioned in the second display area DA2.

Each light emitting element EL may include a first electrode ET1 (e.g., an anode) connected to a transistor Tpx through a first bridge electrode BR1 and/or a second bridge electrode BR2 and a light emitting layer EML (e.g., an organic light emitting layer) and a second electrode ET2 (e.g., a cathode) sequentially disposed on the first electrode ET1. In an embodiment, each light emitting element EL may further include a first intermediate layer (e.g., a hole layer including a hole transport layer) interposed between the first electrode ET1 and the light emitting layer EML and a second intermediate layer (e.g., an electron layer including an electron transport layer) interposed between the light emitting layer EML and the second electrode ET2.

The first electrode ET1 of each light emitting element EL may include a conductive material and may be disposed on the circuit layer 120. For example, the first electrode ET1 may be disposed on the sixth insulating layer 127 in each sub-emission area SEA. In an embodiment, the first electrode ET1 may include a metal material having high reflectivity. For example, the first electrode ET1 may have a single-layer structure of molybdenum (Mo), titanium (Ti), copper (Cu) or aluminum (Al) or may have a multilayer structure (e.g., ITO/Mg, ITO/MgF, ITO/Ag, or ITO/Ag/ITO) including indium-tin-oxide (ITO), indium-zinc-oxide (IZO), zinc oxide (ZnO), indium oxide (In₂O₃), silver (Ag), magnesium (Mg), aluminum (Al), platinum (Pt), lead (Pb), gold (Au) or nickel (Ni).

The light emitting layer EML of each light emitting element EL may include a high molecular material or a low molecular material. Light emitted from the light emitting layer EML may be used to display an image. In an embodiment, the light emitting layer EML may be provided for each subpixel SPX, and the light emitting layer EML of each subpixel SPX may emit visible light of a color corresponding to the subpixel SPX. In an embodiment, the light emitting layer EML may be a common layer (or integral layer) shared by subpixels SPX of different colors, and a wavelength conversion layer and/or a color filter corresponding to a color (or wavelength band) of light to be emitted from each subpixel SPX may be disposed in sub-emission areas SEA of at least some of the subpixels SPX.

The second electrode ET2 of each light emitting element EL may include a conductive material and may be connected to the second power line PL2. In an embodiment, the second electrode ET2 may be a common layer (or integral layer) formed over the entire display area DA to cover the light emitting layers EML and the pixel defining layer 131. In an embodiment, the second electrode ET2 may be made of a transparent conductive material (TCO) capable of transmitting light, such as ITO or IZO, or a semi-transmissive conductive material such as magnesium (Mg), silver (Ag) or an alloy of Mg and Ag. In case that the second electrode ET2 is made of a semi-transmissive conductive material, the light output efficiency may be improved and enhanced by a microcavity effect.

In an embodiment, a light emitting element EL may have an area (or size) corresponding to an area (or size) of each sub-emission area SEA. For example, a light emitting element EL may include a light emitting layer EML having an area (or size) corresponding to the area (or size) of each sub-emission area SEA. For example, the first light emitting element EL1 may include a light emitting layer EML having an area (or size) corresponding to the area (or size) of the sub-emission area SEA of a subpixel SPX (e.g., a subpixel SPX of the first pixel PX1) positioned in the first display area DA1, and the second light emitting element EL2 may include a light emitting layer EML having an area (or size) corresponding to the area (or size) of the sub-emission area SEA of a subpixel SPX (e.g., a subpixel SPX of the second pixel PX2) positioned in the second display area DA2.

In an embodiment, the area (or size) of the sub-emission area SEA, in which the second light emitting element EL2 is formed, may be larger than the area (or size) of the sub-emission area SEA in which the first light emitting element EL1 is formed, and the second light emitting element EL2 may include a light emitting layer EML having a larger area (or larger size) than that of the light emitting layer EML of the first light emitting element EL1. For example, a first-color subpixel SPX11 of the first pixel PX1 may include the first light emitting element EL1 (e.g., a first organic light emitting diode) including a light emitting layer EML having an area (or size) corresponding to an area (or size) of a first-color first sub-emission area SEA11, and a first-color subpixel SPX21 of the second pixel PX2 may include the second light emitting element EL2 (e.g., a second organic light emitting diode) including a light emitting layer EML having an area (or size) corresponding to an area (or size) of a first-color second sub-emission area SEA21.

The pixel defining layer 131 may have openings corresponding to the sub-emission areas SEA, respectively, and may surround the emission areas EA. For example, the pixel defining layer 131 may be formed to cover edge portions of the first electrode ET1 of each light emitting element EL and may include an opening exposing the other portion of the first electrode ET1. An area where the exposed first electrode ET1 and the light emitting layer EML overlap (or an area including the area where the exposed first electrode ET1 and the light emitting layer EML overlap) may be defined as a sub-emission area SEA of each subpixel SPX.

In an embodiment, the pixel defining layer 131 may include at least one organic layer including an organic insulating material. For example, the pixel defining layer 131 may include polyacrylates resin, epoxy resin, phenolic resin, polyamides resin, polyimides resin, unsaturated polyesters resin, polyphenylenethers resin, polyphenylenesulfides resin or benzocyclobutene (BCB) or may include other organic insulating materials.

The encapsulation layer 140 may be disposed on the light emitting element layer 130 in the display area DA and a non-display area NA around the display area DA. The encapsulation layer 140 may block penetration (or permeation) of oxygen or moisture into the light emitting element layer 130 and may reduce electrical or physical shock to the circuit layer 120 and the light emitting element layer 130.

In an embodiment, the encapsulation layer 140 may include a first encapsulation layer 141, a second encapsulation layer 142, and a third encapsulation layer 143 sequentially disposed on the light emitting element layer 130. The first encapsulation layer 141 and the third encapsulation layer 143 may include an inorganic insulating material, and the second encapsulation layer 142 may include an organic insulating material.

According to the embodiments of FIGS. 9 through 12, the second pixel PX2 may include at least one sub-emission area SEA having a larger area (or larger size) than that of the first pixel PX1. Accordingly, a second emission area EA2 of the second pixel PX2 may have a larger area (or larger size) than that of a first emission area EA1 of the first pixel PX1.

In case that the area (or size) of a sub-emission area SEA is increased, the area (or size) of a light emitting element EL disposed in the sub-emission area SEA (e.g., the area (or size) of a light emitting layer EML having an area (or size) corresponding to an area (or size) of each sub-emission area SEA) may be increased. Accordingly, although a pixel circuit PXC supplies a uniform driving current to the light emitting element EL in response to each data signal, the density of the current flowing through the light emitting element EL and the light emitting layer EML included in the light emitting element EL may decrease.

Although the light emitting elements EL emit light at the same time and luminance, amounts of deterioration of the light emitting elements EL may be different according to the density of a current flowing through the light emitting layer EML of each of the light emitting elements EL. For example, in case that the density of a current flowing through a light emitting layer EML decreases, the amount of deterioration of a corresponding light emitting element EL may decrease. Therefore, the deterioration of the light emitting elements EL and the second pixel PX2 including the light emitting elements EL may be reduced or minimized by reducing the density of a current flowing through each light emitting element EL of the second pixel PX2.

According to the above-described embodiments, afterimages caused by deterioration of the light emitting elements EL and the pixels PX (e.g., second pixels PX2) including the light emitting elements EL may be prevented or minimized, and the image quality and lifespan of the display device 100 may be improved or enhanced. For example, in the display device 100 according to the above-described embodiments, the deterioration of the light emitting elements EL and the pixels PX may be reduced or minimized in advance. Therefore, the image quality of the display device 100 may be improved or enhanced without side effects (e.g., collisions between driving programs or image quality problems caused by the operation of a deterioration compensation program) that occur in a display device in which a reduction in image quality due to deterioration of the light emitting elements EL and the pixels PX is compensated for by a driving circuit.

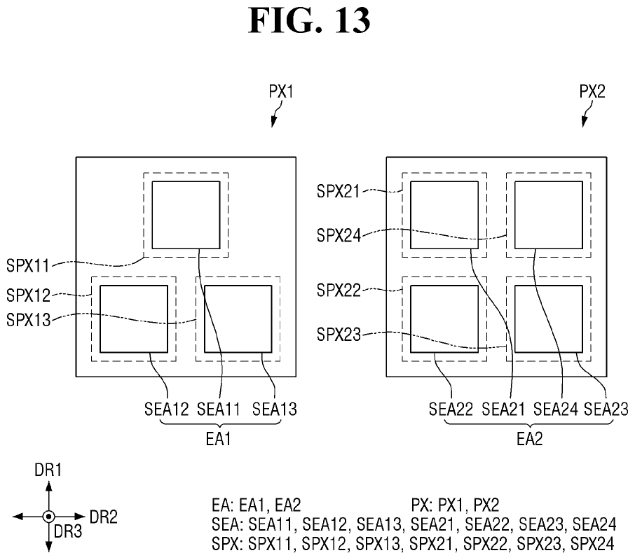

FIG. 13 is a schematic plan view illustrating a first pixel PX1 and a second pixel PX2 according to an embodiment. For example, FIG. 13 shows an embodiment different from the embodiment of FIG. 11 in relation to the first pixel PX1 and the second pixel PX2.

Referring to FIG. 13 in addition to FIGS. 1 through 12, the first pixel PX1 and the second pixel PX2 may include different numbers of subpixels SPX. For example, the second pixel PX2 may include a greater number of subpixels SPX than the first pixel PX1 by further including at least one auxiliary subpixel (e.g., a fourth-color subpixel SPX24) that improves light emission luminance.

In an embodiment, the first pixel PX1 may include a first-color subpixel SPX11 including a first-color first sub-emission area SEA11 and emitting light of a first color, a second-color subpixel SPX12 including a second-color first sub-emission area SEA12 and emitting light of a second color, and a third-color subpixel SPX13 including a third-color first sub-emission area SEA13 and emitting light of a third color. The second pixel PX2 may include a first-color subpixel SPX21 including a first-color second sub-emission area SEA21 and emitting light of the first color, a second-color subpixel SPX22 including a second-color second sub-emission area SEA22 and emitting light of the second color, and a third-color subpixel SPX23 including a third-color second sub-emission area SEA23 and emitting light of the third color and may further include at least one subpixel SPX. For example, the second pixel PX2 may further include the fourth-color subpixel SPX24 including a fourth-color second sub-emission area SEA24 and emitting light of a fourth color. In another example, the second pixel PX2 may further include one or more subpixels SPX emitting light of the first color, the second color, or the third color. For example, the second pixel PX2 may include at least two first-color subpixels SPX21, at least two second-color subpixels SPX22, and/or at least two third-color subpixels SPX23.

In an embodiment, each sub-emission area SEA included in the first pixel PX1 may have the same area (or size) as a corresponding sub-emission area SEA of the second pixel PX2. For example, the first-color first sub-emission area SEA11 and the first-color second sub-emission area SEA21 may have the same area (or size) as each other. For example, the second-color first sub-emission area SEA12 and the second-color second sub-emission area SEA22 may have the same area (or size) as each other, and the third-color first sub-emission area SEA13 and the third-color second sub-emission area SEA23 may have the same area (or size) as each other.

The second pixel PX2 further including at least one subpixel SPX (e.g., the fourth-color subpixel SPX24) may include an emission area EA having a larger area (or larger size) than that of the first pixel PX1. For example, the area (or size) of a second emission area EA2 may be larger than the area (or size) of a first emission area EA1.

According to the above-described embodiment, the second pixel PX2 may include an additional subpixel SPX. Accordingly, a driving current flowing through each subpixel SPX of the second pixel PX2 may be reduced. For example, the luminance of the second pixel PX2 may be complemented or increased by light emission of the fourth-color subpixel SPX24. Accordingly, light emission luminance of each of the subpixels SPX formed in the second pixel PX2 may be reduced. Therefore, according to the above-described embodiment, the deterioration of a light emitting element EL and the second pixel PX2 may be reduced or minimized by reducing a current (or density of current) flowing through the light emitting element EL formed in each subpixel SPX of the second pixel PX2.

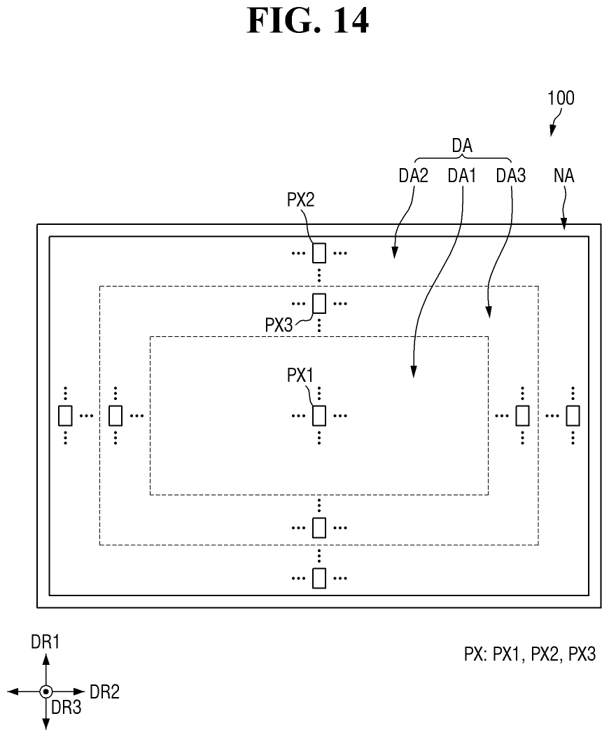

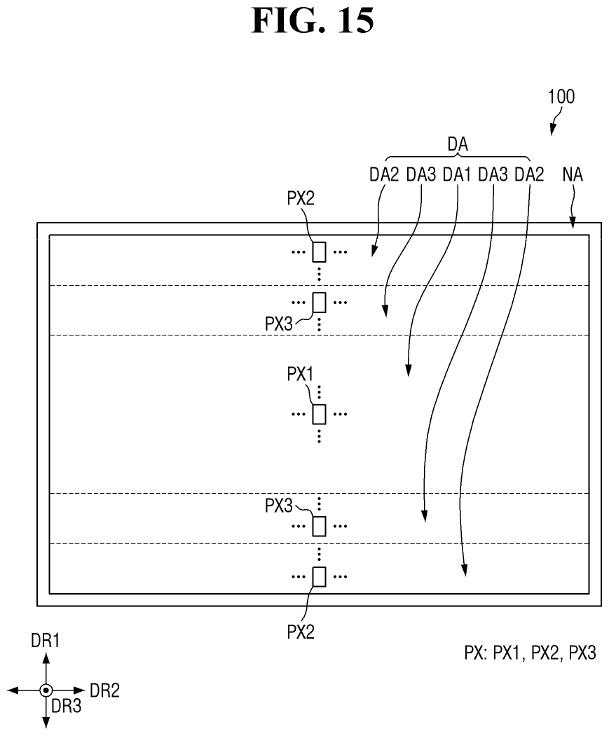

FIG. 14 is a schematic plan view of a display device 100 according to an embodiment. FIG. 15 is a schematic plan view of a display device 100 according to an embodiment. For example, FIGS. 14 and 15 show modifications of the embodiments of FIGS. 9 and 10.

Referring to FIGS. 14 and 15 in addition to FIGS. 1 through 13, a display area DA may further include at least one third display area DA3 positioned between a first display area DA1 and a second display area DA2. For example, the third display area DA3 may be positioned between the first display area DA1 and the second display area DA2 in at least the first direction DR1.

In an embodiment, as illustrated in FIG. 14, the first display area DA1 may be positioned at the center portion of the display area DA, and the third display area DA3 may be positioned outside the first display area DA1 to surround the first display area DA1. The second display area DA2 may be positioned at edge portions of the display area DA and may surround the third display area DA3.

In an embodiment, as illustrated in FIG. 15, the first display area DA1 may be positioned at the center portion of the display area DA in the first direction DR1, and the third display area DA3 may be positioned on at least one side of the first display area DA1 in the first direction DR1. For example, the third display area DA3 may be positioned on sides (e.g., opposite sides) of the first display area DA1 in the first direction DR1. For example, the display area DA may include two third display areas DA3 separated from each other with the first display area DA1 interposed therebetween and two second display areas DA2 separated from each other with the first display area DA1 and the third display areas DA3 interposed therebetween and positioned at an upper edge portion and a lower edge portion of the display area DA.

The display device 100 may include first pixels PX1 positioned in the first display area DA1, second pixels PX2 positioned in the second display area DA2, and third pixels PX3 positioned in the third display area DA3. The first pixels PX1, the second pixels PX2, and the third pixels PX3 may include emission areas EA having different areas (or different sizes). For example, each third pixel PX3 positioned in the third display area DA3 may include an emission area EA having a larger area (or larger size) than a first emission area EA1 of each first pixel PX1 and having a smaller area (or smaller size) than a second emission area EA2 of each second pixel PX2.

In an embodiment, the display area DA may be divided into four or more areas in a direction from the center portion to the edge portions of the display area DA as described above. For example, the area (or size) of the pixels PX positioned in each area may be more finely changed (e.g., expanded) gradually and/or in stages from an area positioned at the center portion of the display area DA toward an area positioned at the edge portions of the display area DA.

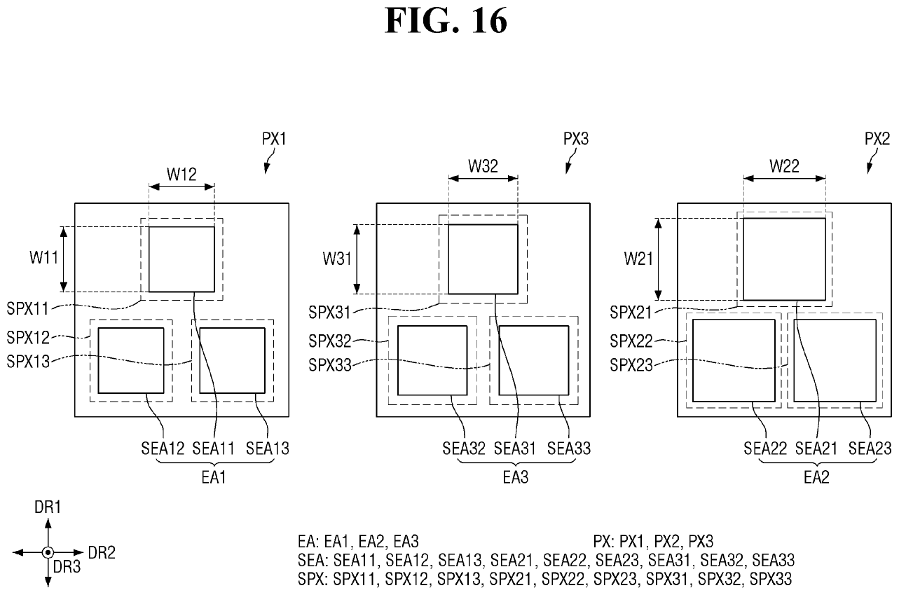

FIG. 16 is a schematic plan view illustrating a first pixel PX1, a second pixel PX2, and a third pixel PX3 according to an embodiment. In FIG. 16, the first pixel PX1, the second pixel PX2, and the third pixel PX3 are illustrated as being disposed side by side for comparison between the first pixel PX1, the second pixel PX2, and the third pixel PX3.

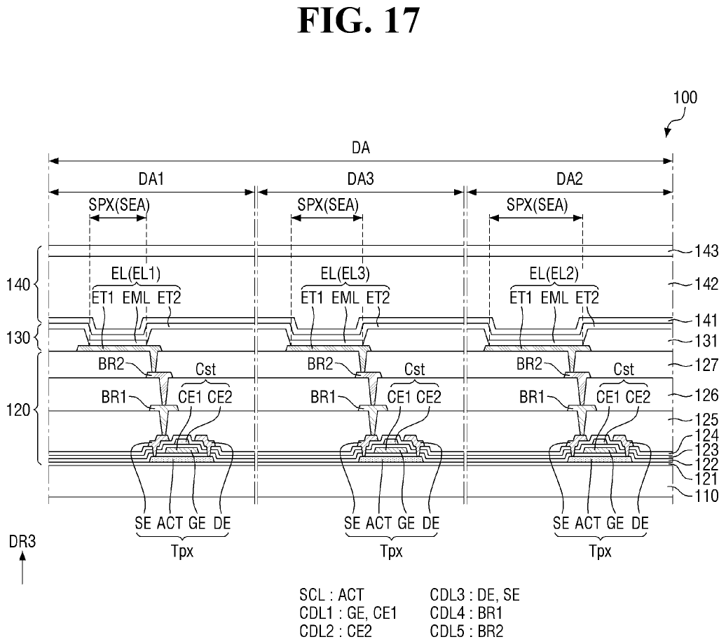

FIG. 17 is a schematic cross-sectional view of a display device 100 according to an embodiment. For example, FIG. 17 schematically illustrates a cross-section of a portion of a display area DA which corresponds to an area where three subpixels SPX positioned in a first display area DA1, a second display area DA2, and a third display area DA3 are disposed.

In describing the embodiment of FIGS. 16 and 17, elements similar or identical to those of the embodiment of FIGS. 11 and 12 will be indicated by the same reference numerals, and a detailed description thereof will be omitted for descriptive convenience.

Referring to FIG. 16 in addition to FIGS. 1 through 15, the third pixel PX3 may include a third emission area EA3 (e.g., an emission area EA of the third pixel PX3) including sub-emission areas SEA of the third pixel PX3.

In an embodiment, the third pixel PX3 may include a first-color subpixel SPX31 emitting light of a first color, a second-color subpixel SPX32 emitting light of a second color, and a third-color subpixel SPX33 emitting light of a third color. The first-color subpixel SPX31 of the third pixel PX3 may include a first-color third sub-emission area SEA31 having a light emitting element EL and emitting light of the first color (e.g., an emission area of the first-color subpixel SPX31 included in the third pixel PX3). The second-color subpixel SPX32 of the third pixel PX3 may include a second-color third sub-emission area SEA32 having a light emitting element EL and emitting light of the second color (e.g., an emission area of the second-color subpixel SPX32 included in the third pixel PX3). The third-color subpixel SPX33 of the third pixel PX3 may include a third-color third sub-emission area SEA33 having a light emitting element EL and emitting light of the third color (e.g., an emission area of the third-color subpixel SPX33 included in the third pixel PX3). The third emission area EA3 of the third pixel PX3 may include the first-color third sub-emission area SEA31, the second-color third sub-emission area SEA32, and the third-color third sub-emission area SEA33.

The third emission area EA3 may have a larger area (or larger size) than a first emission area EA1 and a smaller area (or smaller size) than a second emission area EA2. For example, the sum of the areas (or sizes) of the sub-emission areas SEA included in the subpixels SPX of the third pixel PX3 may be greater than the sum of the areas (or sizes) of sub-emission areas SEA included in subpixels SPX of the first pixel PX1 and may be smaller than the sum of the areas (or sizes) of sub-emission areas SEA included in subpixels SPX of the second pixel PX2. For example, the sum of the areas (or sizes) of the first-color third sub-emission area SEA31, the second-color third sub-emission areas SEA32, and the third-color third sub-emission area SEA33 may be greater than the sum of the areas (or sizes) of first-color first sub-emission area SEA11, the second-color first sub-emission area SEA12, and the third-color first sub-emission area SEA13 and smaller than the sum of the areas (or sizes) of first-color second sub-emission area SEA21, the second-color second sub-emission area SEA22, and the third-color second sub-emission area SEA23.

In an embodiment, the first pixel PX1, the second pixel PX2, and the third pixel PX3 may include the same number of sub-emission areas SEA. For example, at least some of the sub-emission areas SEA included in the first pixel PX1, the second pixel PX2 and the third pixel PX3 and corresponding to each other may have different areas (or different sizes). For example, at least one sub-emission area SEA included in the third pixel PX3 may have a greater width than a corresponding sub-emission area SEA of the first pixel PX1 in at least one of the first direction DR1 and the second direction DR2. For example, at least one sub-emission area SEA included in the third pixel PX3 may have a smaller width than a corresponding sub-emission area SEA of the second pixel PX2 in at least one of the first direction DR1 and the second direction DR2. For example, in case that the first-color third sub-emission area SEA31 of the third pixel PX3 has a fifth width W31 in the first direction DR1 and a sixth width W32 in the second direction DR2, the fifth width W31 may be greater than a first width W11 and smaller than a third width W21, and/or the sixth width W32 may be greater than a second width W12 and smaller than a fourth width W22. Accordingly, the area (or size) of the first-color third sub-emission area SEA31 may be larger than the area (or size) of the first-color first sub-emission area SEA11 and smaller than the area (or size) of the first-color second sub-emission area SEA21.

In an embodiment, the second-color third sub-emission area SEA32 may have a greater width than the second-color first sub-emission area SEA12 in at least one of the first direction DR1 and the second direction DR2 and may have a smaller width than the second-color second sub-emission area SEA22. Accordingly, the area (or size) of the second-color third sub-emission area SEA32 may be larger than the area (or size) of the second-color first sub-emission area SEA12 and smaller than the area (or size) of the second-color second sub-emission area SEA22.

In an embodiment, the third-color third sub-emission area SEA33 may have a greater width than the third-color first sub-emission area SEA13 in at least one of the first direction DR1 and the second direction DR2 and may have a smaller width than the third-color second sub-emission area SEA23. Accordingly, the area (or size) of the third-color third sub-emission area SEA33 may be larger than the area (or size) of the third-color first sub-emission area SEA13 and smaller than the area (or size) of the third-color third sub-emission area SEA32.

Referring to FIG. 17 in addition to FIGS. 1 through 16, a light emitting element layer 130 may further include a third light emitting element EL3 disposed in a sub-emission area SEA of a subpixel SPX positioned in the third display area DA3 (e.g., any one sub-emission area SEA of a third pixel PX3). In an embodiment, the third light emitting element EL3 may include a light emitting layer EML having an area (or size) corresponding to an area (or size) of a sub-emission area SEA of a subpixel SPX positioned in the third display area DA3 (e.g., a subpixel SPX of the third pixel PX3). For example, the third light emitting element EL3 may include a light emitting layer EML having a larger area (or larger size) than a light emitting layer EML of a first light emitting element EL1 and a smaller area (or smaller size) than a light emitting layer EML of a second light emitting element EL2. For example, a first-color subpixel SPX31 of the third pixel PX3 may include a third light emitting element EL3 (e.g., a third organic light emitting diode) including a light emitting layer EML having an area (or size) corresponding to an area (or size) of a first-color third sub-emission area SEA31.

According to the embodiments of FIGS. 14 through 17, the area (or size) of the first emission area EA1 in the first display area DA1, the area (or size) of the third emission area EA3 in the third display area DA3, and the area (or size) of the second emission area EA2 in the second display area DA2 sequentially disposed in a direction from the center portion of the display area DA to the edge portions of the display area DA may be changed (e.g., expanded) gradually and/or in stages. Accordingly, the deterioration of second pixels PX2 and third pixels PX3 positioned at the edge portions of and/or around the display area DA may be reduced or minimized, and a boundary between the first display area DA1, the third display area DA3 and the second display area DA2 may be prevented from being viewed or recognized. In an embodiment, the display area DA may be divided into a larger number of areas in the same way as described above, and emission areas of pixels PX positioned in each area may be more finely and gradually expanded from an area positioned at the center portion of the display area DA toward an area positioned at the edge portions of the display area DA.

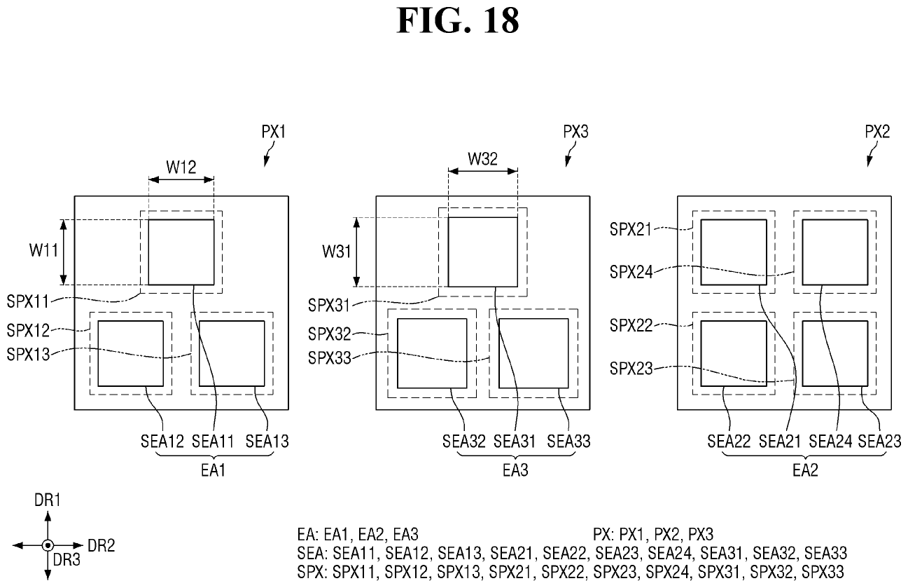

FIG. 18 is a schematic plan view illustrating a first pixel PX1, a second pixel PX2, and a third pixel PX3 according to an embodiment. For example, FIG. 18 may show an embodiment different from the embodiment of FIG. 16 in relation to the second pixel PX2.

Referring to FIG. 18 in addition to FIGS. 1 through 17, the second pixel PX2 may include a different number of subpixels SPX from the first pixel PX1 and the third pixel PX3. For example, the second pixel PX2 may include a greater number of subpixels SPX than the first pixel PX1 and the third pixel PX3. Accordingly, a second emission area EA2 of the second pixel PX2 may have a larger area (or larger size) than a first emission area EA1 of the first pixel PX1 and a third emission area EA3 of the third pixel PX3.

As in the above-described embodiment, the areas (or sizes) of emission areas EA of pixels PX formed in a first display area DA1, a second display area DA2, and/or a third display area DA3 may be adjusted to be different by varying the number of subpixels SPX formed in each pixel PX and/or the areas (or sizes) of sub-emission areas SEA of the subpixels SPX. For example, in the second display area DA2 positioned at edge portions of a display area DA and having a relatively large cumulative light emission amount of the pixels PX, the area (or size) of the sub-emission area SEA of each subpixel SPX may be expanded, or the number of subpixels SPX may be increased. Accordingly, the density of a driving current flowing through a light emitting element EL of each subpixel SPX positioned in at least the second display area DA2 may be reduced, and the deterioration of the light emitting element EL and a pixel PX (or a subpixel PX) including the light emitting element EL may be reduced or minimized.

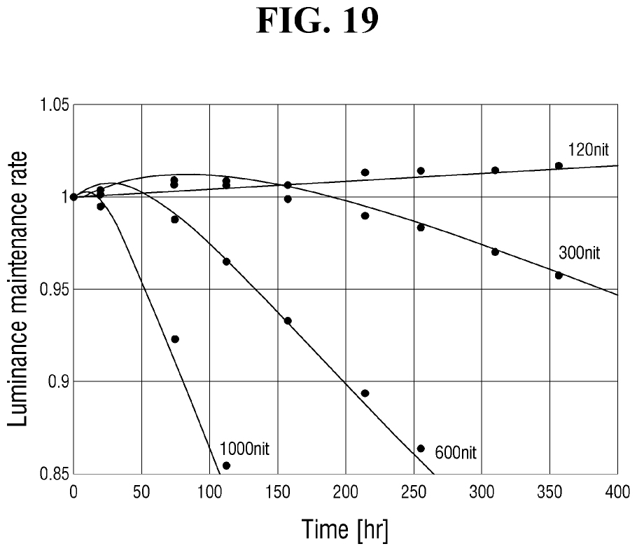

FIG. 19 is a graph illustrating the luminance maintenance rate of a light emitting element EL with respect to light emission time and light emission luminance.

Referring to FIG. 19 in addition to FIGS. 1 through 18, as the cumulative light emission amount of the light emitting element EL increases, the light emitting element EL may deteriorate. For example, the light emitting element EL may deteriorate as the light emission time increases. Accordingly, the luminance maintenance rate of the light emitting element EL may gradually decrease. The degree (e.g., amount) and/or rate of deterioration of the light emitting element EL may vary according to the light emission luminance of the light emitting element EL (or the density of a current flowing through the light emitting element EL according to the light emission luminance). For example, as the light emission luminance of the light emitting element EL increases, the density of a current flowing through a light emitting layer EML may increase, thereby causing the light emitting element EL to deteriorate at a faster rate. For example, in case that a current corresponding to a luminance of about 1000 nit flows through the light emitting element EL, the deterioration of the light emitting element EL may be faster than in case that a current corresponding to a luminance of 600 nit, 300 nit, or 120 nit flows through the light emitting element EL. Accordingly, the luminance maintenance rate of the light emitting element EL with respect to the light emission time of the light emitting element EL may rapidly decrease. Therefore, as in the above-described embodiments, the area (or size) of each sub-emission area SEA positioned in a second display area DA2 may be expanded, or an additional subpixel SPX (e.g., a fourth-color subpixel SPX24), which compensates for luminance, may be formed in a second pixel PX2 of the second display area DA2 to reduce the density of a driving current flowing through the light emitting element EL formed in each sub-emission area SEA of the second pixel PX2. For example, the deterioration of the light emitting element EL formed in each subpixel SPX may be reduced or minimized.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a display area comprising a first display area and a second display area disposed around the first display area;
a first pixel disposed in the first display area and comprising a first emission area; and
a second pixel disposed in the second display area and comprising a second emission area,
wherein the second emission area has a larger size than the first emission area.

2. The display device of claim 1, wherein
the first pixel and the second pixel comprise a same number of subpixels, and
a sum of sizes of sub-emission areas of the subpixels of the second pixel is greater than a sum of sizes of sub-emission areas of the subpixels of the first pixel.

3. The display device of claim 1, wherein
each of the first pixel and the second pixel comprises a first-color subpixel emitting light of a first color,
the first-color subpixel of the first pixel comprises a first-color first sub-emission area having a first size, and
the first-color subpixel of the second pixel comprises a first-color second sub-emission area having a second size larger than the first size of the first-color first sub-emission area.

4. The display device of claim 3, wherein
the first-color subpixel of the first pixel comprises an organic light emitting diode comprising a light emitting layer having a size corresponding to the first size of the first-color first sub-emission area, and
the first-color subpixel of the second pixel comprises an organic light emitting diode comprising a light emitting layer having a size corresponding to the second size of the first-color second sub-emission area.

5. The display device of claim 3, wherein
each of the first pixel and the second pixel comprises a second-color subpixel emitting light of a second color, and
the second-color subpixel of the second pixel comprises a second-color second sub-emission area having a larger size than a second-color first sub-emission area of the second-color subpixel of the first pixel.

6. The display device of claim 5, wherein
each of the first pixel and the second pixel comprises a third-color subpixel emitting light of a third color, and
the third-color subpixel of the second pixel comprises a third-color second sub-emission area having a larger size than a third-color first sub-emission area of the third-color subpixel of the first pixel.

7. The display device of claim 1, wherein
the first pixel and the second pixel comprise different numbers of subpixels, and
the second pixel comprises a larger number of subpixels than the first pixel.

8. The display device of claim 1, wherein
the first pixel comprises:
a first-color subpixel emitting light of a first color,
a second-color subpixel emitting light of a second color, and
a third-color subpixel emitting light of a third color, and
the second pixel comprises:
a first-color subpixel emitting light of the first color,
a second-color subpixel emitting light of the second color,
a third-color subpixel emitting light of the third color, and
a fourth-color subpixel emitting light of a fourth color.

9. The display device of claim 8, wherein
the first-color subpixel of the first pixel and the first-color subpixel of the second pixel comprise sub-emission areas having a same size,
the second-color subpixel of the first pixel and the second-color subpixel of the second pixel comprise sub-emission areas having a same size, and
the third-color subpixel of the first pixel and the third-color subpixel of the second pixel comprise sub-emission areas having a same size.

10. The display device of claim 8, wherein the light of the first color, the light of the second color, the light of the third color, and the light of the fourth color are red light, green light, blue light, and white light, respectively.

11. The display device of claim 1, wherein
the first display area is disposed at a center portion of the display area in at least a first direction, and
the second display area is disposed at edge portions of the display area in the first direction.

12. The display device of claim 11, wherein the second display area is disposed at the edge portions of the display area in the first direction and a second direction intersecting the first direction and surrounds the first display area.

13. The display device of claim 11, wherein
the first direction corresponds to a vertical direction of the display area, and
the second display area is disposed at at least one of an upper edge portion and a lower edge portion of the display area.

14. The display device of claim 1, wherein
the display area displays an image comprising a logo image or a banner image, and
the second display area comprises an area where the logo image or the banner image is displayed.

15. The display device of claim 1, wherein
the display area further comprises a third display area disposed between the first display area and the second display area, and
the third display area comprises a third pixel.

16. The display device of claim 15, wherein the third pixel comprises a third emission area having a larger size than the first emission area and a smaller size than the second emission area.

17. A display device comprising:
a first display area comprising a first pixel; and
a second display area disposed on sides of the first display area in at least a first direction and comprising a second pixel, wherein
the first pixel comprises a first-color subpixel emitting light of a first color and comprising a sub-emission area having a first size, and
the second pixel comprises a first-color subpixel emitting light of the first color and comprising a sub-emission area having a second size larger than the first size.

18. The display device of claim 17, wherein the first pixel and the second pixel comprise a same number of subpixels.

19. A display device comprising:
a first display area comprising a first pixel; and
a second display area disposed on sides of the first display area in at least a first direction and comprising a second pixel, wherein
each of the first pixel and the second pixel comprises at least two subpixels, and the second pixel comprises a larger number of subpixels than the first pixel.

20. The display device of claim 19, wherein
each of the first pixel and the second pixel comprises a first-color subpixel emitting light of a first color, and
the first-color subpixel of the first pixel and the first-color subpixel of the second pixel comprise sub-emission areas having a same size.
